(19) United States
(12) Patent Application Publication
(10) Pub. No.: US 2026/0190991 A1
(43) Pub. Date: Jul. 2, 2026

(54) THERMAL DISTRIBUTION IN COUPLED SEMICONDUCTOR SYSTEMS

(71) Applicant: Micron Technology, Inc., Boise, ID (US)

(72) Inventors: Amy Rae Griffin, Boise, ID (US); Brent Keeth, Boise, ID (US); James Brian Johnson, Boise, ID (US); Kunal R. Parekh, Boise, ID (US); Eiichi Nakano, Machidashi, Tokyo (JP)

(21) Appl. No.: 19/420,445

(22) Filed: Dec. 15, 2025

Related U.S. Application Data
(60) Provisional application No. 63/740,050, filed on Dec. 30, 2024.

(51) Int. Cl. H10W 40/25; H10W 40/00; H10W 40/20; H10W 80/00; H10W 90/00; H10W 90/10; H10W 90/20

(52) U.S. Cl. CPC H10W 40/255; H10W 40/03; H10W 40/233; H10W 90/10; H10W 90/288; H10W 90/792; H10W 80/312

(57) ABSTRACT

Methods, systems, and devices for thermal distribution in coupled semiconductor systems are described. A coupled semiconductor system may include a first semiconductor component, a second semiconductor component bonded with a first portion of a surface of the first semiconductor component, and a metallic material over a second portion of the surface of the first semiconductor component and adjacent to the second semiconductor component along one or more sides of the second semiconductor component. In some examples, the coupled semiconductor system may be formed by bonding multiple second semiconductor components to the first semiconductor component and forming the metallic material over one or more second portions of the surface of the first semiconductor component (e.g., between second semiconductor components). In some examples, the semiconductor system may be formed by forming trenches (e.g., through a second semiconductor component) and forming the metallic material in the trenches.

### CROSS REFERENCE

The present Application for Patent claims priority to U.S. patent application Ser. No. 63/740,050 by Griffin et al., entitled “THERMAL DISTRIBUTION IN COUPLED SEMICONDUCTOR SYSTEMS,” filed Dec. 30, 2024 which is assigned to the assignee hereof, and which is expressly incorporated by reference in its entirety herein.

### TECHNICAL FIELD

The following relates to one or more semiconductor systems, including thermal distribution in coupled semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports thermal distribution in coupled semiconductor systems in accordance with examples as disclosed herein.

FIG. 2 shows an example of a system that supports thermal distribution in coupled semiconductor systems in accordance with examples as disclosed herein.

FIG. 3 shows an example of a semiconductor system that supports thermal distribution in coupled semiconductor systems in accordance with examples as disclosed herein.

FIGS. 4A and 4B show examples of processing steps that support thermal distribution in coupled semiconductor systems in accordance with examples as disclosed herein.

FIGS. 5A through 5D show examples of processing steps that support thermal distribution in coupled semiconductor systems in accordance with examples as disclosed herein.

FIG. 6 shows an example of a top plan view that supports thermal distribution in coupled semiconductor systems in accordance with examples as disclosed herein.

FIGS. 7 and 8 show flowcharts illustrating a method or methods that support thermal distribution in coupled semiconductor systems in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., memory dies, array dies, memory array dies) or one or more stacks of memory dies that are stacked with a logic die that is operable to access a set of memory arrays distributed across the one or more memory dies. Such a stacked architecture may be implemented as part of a high bandwidth memory (HBM) system or a stacked dynamic random access memory system, among other examples, and may support solutions for memory-centric logic, such as graphics processing units (GPUs), among other implementations. In some examples, an HBM system may include one or more memory dies coupled (e.g., bonded, stacked) with a logic die. In some examples, a stacked system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

A semiconductor system may be formed by coupling semiconductor components (e.g., subcomponents, subsystems) with one another, such as coupling one semiconductor die with another semiconductor die (e.g., in accordance with a chip-to-chip (C2C) bonding), coupling a stack of semiconductor dies with another semiconductor die, coupling respective sets of one or more semiconductor dies with a semiconductor wafer (e.g., in accordance with a chip-to-wafer (C2W) bonding), coupling one semiconductor wafer with another semiconductor wafer (e.g., in accordance with a wafer-to-wafer (W2W) bonding), among other examples. Operations performed by a semiconductor system may generate heat, which may be distributed through the semiconductor system in accordance with various thermal paths of the semiconductor system. In some implementations, an arrangement of materials of a semiconductor system may be associated with a mismatch of thermal conductivities, where some regions of the semiconductor system have a relatively lower thermal conductivity than other regions. For example, some semiconductor systems may include bonding materials or other interface materials between or around the semiconductor components, or one or more regions that lack a material (e.g., air gaps, air interfaces), that have a different thermal conductivity than the semiconductor components themselves, or a different thermal conductivity than a coupling between the semiconductor components (e.g., related to differences in bonding techniques or bonding materials). Additionally, or alternatively, one semiconductor component of the semiconductor system may have a different footprint (e.g., cross-sectional area, as viewed along a stack direction) than another semiconductor component, which also may be associated with a difference in thermal conductivity from one region of the semiconductor system to another. In some examples, a mismatch of thermal conductivities (e.g., along a stack direction, along a thickness direction) in different regions of a semiconductor system may lead to an uneven temperature distribution (e.g., hot spots, which may be related to differences in rejecting generated heat) in the semiconductor system, which may affect the operations performed by the semiconductor system.

In accordance with examples as described herein, a semiconductor system may include a first semiconductor component, a second semiconductor component bonded with a first portion of the surface of the first semiconductor component, and a metallic material over a second portion of the surface of the first semiconductor component and adjacent to the second semiconductor component along one or more sides of the second semiconductor component. The metallic material may be electrically isolated from circuitry of the first semiconductor component and from circuitry of the second semiconductor component (e.g., via a dielectric material liner). The metallic material may provide a thermal path to conduct heat from the first semiconductor component, the second semiconductor component, or both, thereby reducing a likelihood of an uneven temperature distribution in the semiconductor system. In some examples, the semiconductor system may be formed by bonding multiple second semiconductor components with respective portions of the surface of the first semiconductor component and forming the metallic material over one or more second portions of the surface of the first semiconductor component (e.g., between the second semiconductor components). In some other examples, the semiconductor system may be formed by bonding a third semiconductor component (e.g., a wafer, that includes multiple semiconductor dies) with the first semiconductor component, forming trenches in the third semiconductor component (e.g., between the multiple second semiconductor components), and forming the metallic material in the trenches.

In addition to applicability in memory systems as described herein, techniques for thermal distribution in coupled semiconductor systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by supporting, via the metallic material, improved heat rejection (e.g., improved heat dissipation or more-even heat distributions), which may support relatively-higher power and higher component density semiconductor systems, among other benefits.

Features of the disclosure are illustrated and described in the context of systems and architectures. Features of the disclosure are further illustrated and described in the context of semiconductor systems, processing operations, and flowcharts.

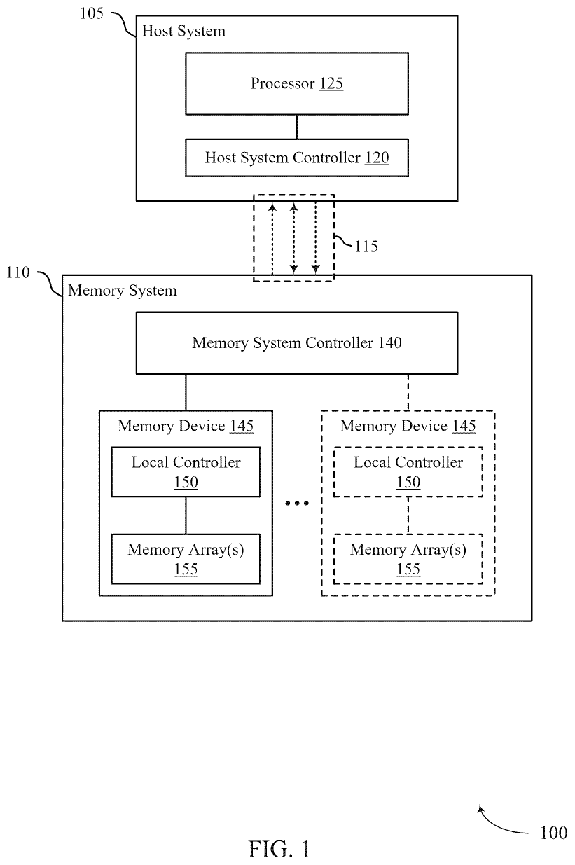

FIG. 1 shows an example of a system 100 that supports thermal distribution in coupled semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Operations performed by the system 100 may generate heat, which may be distributed through the system 100 in accordance with various thermal paths of the system 100. In some implementations, an arrangement of materials of a system 100 may be associated with a mismatch of thermal conductivities, where some regions of the system 100 have a relatively lower thermal conductivity than other regions. For example, some systems 100 may include bonding materials or other interface materials between or around the semiconductor components, or one or more regions that lack a material (e.g., air gaps, air interfaces), that have a different thermal conductivity than the semiconductor components themselves, or a different thermal conductivity than a coupling between the semiconductor components (e.g., related to differences in bonding techniques or bonding materials). Additionally, or alternatively, one semiconductor component of the system 100 may have a different footprint (e.g., cross-sectional area, as viewed along a stack direction) than another semiconductor component, which also may be associated with a difference in thermal conductivity from one region of the system 100 to another. In some examples, a mismatch of thermal conductivities (e.g., along a stack direction, along a thickness direction) in different regions of a system 100 may lead to an uneven temperature distribution (e.g., hot spots, which may be related to differences in rejecting generated heat) in the system 100, which may affect the operations performed by the system 100.

In accordance with examples as described herein, a system 100 may include a first semiconductor component, a second semiconductor component bonded with a first portion of a surface of the first semiconductor component, and a metallic material over a second portion of the surface of the first semiconductor component and adjacent to the second semiconductor component along one or more sides of the second semiconductor component. The metallic material may be electrically isolated from circuitry of the first semiconductor component and from the circuitry of the second semiconductor component (e.g., via a dielectric material liner). The metallic material may provide a thermal path to conduct heat from the first semiconductor component, thereby reducing a likelihood of uneven temperature distribution in the system 100. In some examples, the system 100 may be formed by bonding multiple second semiconductor components with respective portions of the surface of the first semiconductor component and forming the metallic material over one or more second portions of the surface of the first semiconductor component (e.g., between second semiconductor components). In some other examples, the system 100 may be formed by bonding a third semiconductor component (e.g., a wafer, that includes multiple semiconductor dies) with the first semiconductor component, forming trenches in the third semiconductor component (e.g., between second semiconductor components), and forming the metallic material in the trenches.

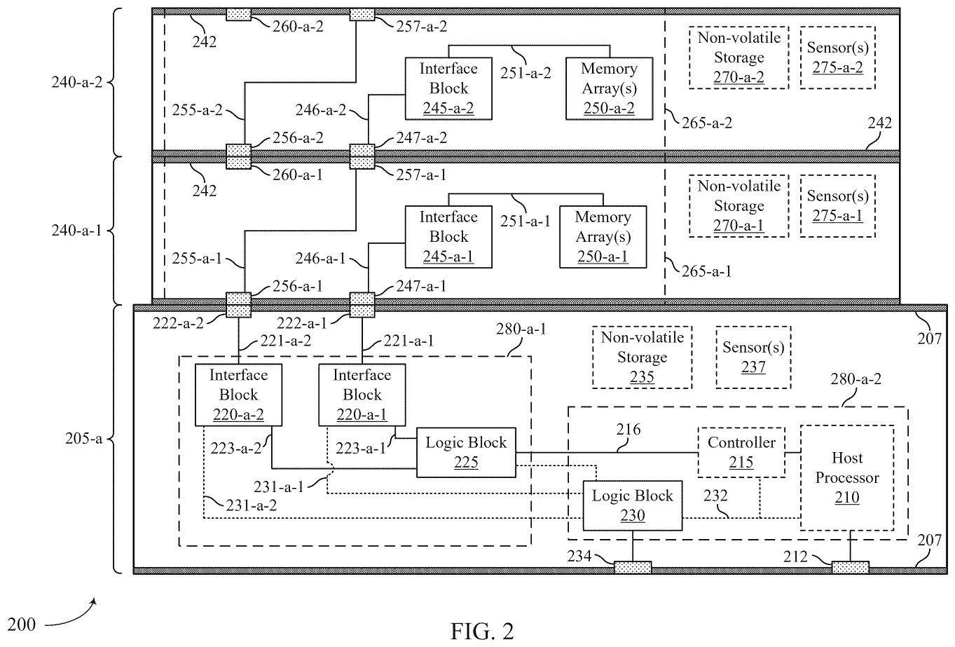

FIG. 2 shows an example of a system 200 (e.g., a semiconductor system, a system of coupled semiconductor dies, an HBM system, a stacked system) that supports thermal distribution in coupled semiconductor systems in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Operations performed by the system 200 may generate heat, which may be distributed through the system 200 in accordance with various thermal paths of the system 200. In some implementations, an arrangement of materials of a system 200 may be associated with a mismatch of thermal conductivities, where some regions of the system 200 have a relatively lower thermal conductivity than other regions. For example, some systems 200 may include bonding materials or other interface materials between or around the semiconductor components, or one or more regions that lack a material (e.g., air gaps, air interfaces), that have a different thermal conductivity than the semiconductor components themselves, or a different thermal conductivity than a coupling between the semiconductor components (e.g., related to differences in bonding techniques or bonding materials). Additionally, or alternatively, one semiconductor component of the system 200 may have a different footprint (e.g., cross-sectional area, as viewed along a stack direction) than another semiconductor component, which also may be associated with a difference in thermal conductivity from one region of the system 200 to another. In some examples, a mismatch of thermal conductivities (e.g., along a stack direction, along a thickness direction) in different regions of a system 200 may lead to an uneven temperature distribution (e.g., hot spots, which may be related to differences in rejecting generated heat) in the system 200, which may affect the operations performed by the system 200.

In accordance with examples as described herein, a system 200 may include a first semiconductor component (e.g., a die 205, a wafer of dies 205), a second semiconductor component (e.g., a die 240, a stack of dies 240, a wafer of dies 240, a stack of wafers each including dies 240) bonded with a first portion of a surface of the first semiconductor component, and a metallic material over a second portion of the surface of the first semiconductor component and adjacent to the second semiconductor component along one or more sides of the second semiconductor component. The metallic material may be electrically isolated from circuitry of the first semiconductor component and from the circuitry of the second semiconductor component (e.g., via a dielectric material liner). The metallic material may provide a thermal path to conduct heat from the first semiconductor component, thereby reducing a likelihood of uneven temperature distribution in the system 200.

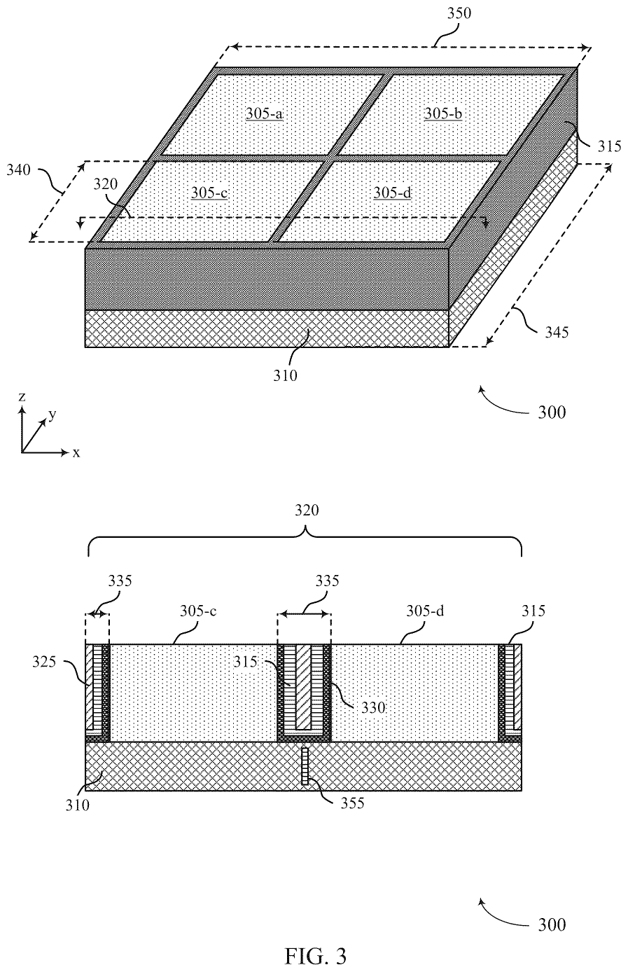

FIG. 3 shows an example of a semiconductor system 300 that supports thermal distribution in coupled semiconductor systems in accordance with examples as disclosed herein. Aspects of the semiconductor system 300 may be described with reference to an x-direction, a y-direction, and a z-direction of the illustrated coordinate system, where the z-direction may be illustrative of a direction (e.g., a vertical direction, a thickness direction, a stack direction) that is orthogonal, or otherwise relative, to a surface in an xy-plane (e.g., a substrate plane, a coupling plane) of the semiconductor system 300. Although FIG. 3 illustrates examples of relative dimensions and quantities of various features, aspects of the semiconductor system 300 may be implemented with other relative dimensions or quantities of such features in accordance with examples as disclosed herein.

The semiconductor system 300 includes semiconductor components 305 (e.g., a semiconductor component 305-a, a semiconductor component 305-b, a semiconductor component 305-c, and a semiconductor component 305-d) and a semiconductor component 310. Although FIG. 3 illustrates an example of a semiconductor system 300 that includes four semiconductor components 305 and one semiconductor component 310, a semiconductor system 300 in accordance with the described techniques may include any quantity of one or more semiconductor components 305 coupled with one or more semiconductor components 310.

Each of the semiconductor components 305 may be coupled with (e.g., physically coupled with, bonded with) the semiconductor component 310. In some examples, the semiconductor component 310 may be a semiconductor wafer, a portion thereof (e.g., a semiconductor die cut from a semiconductor wafer), or a stack of multiple semiconductor dies. Each semiconductor component 305 may be a single semiconductor die, or may be a stack of multiple semiconductor dies. A semiconductor component 305 may be referred to as a memory cube (e.g., a DRAM cube) based on the three-dimensional structure of one or more semiconductor dies that form the semiconductor component 305. The semiconductor components 305 may each include electrically operable circuitry (e.g., functional circuitry), which may be supported by a respective communicative coupling (e.g., electrical coupling) between at least the semiconductor component 310 and each semiconductor component 305 and, in some examples, a communicative coupling with a component outside the semiconductor system 300 (e.g., an interfacing component).

In some implementations, the semiconductor system 300 may include at least some features of a memory system 110. For example, each semiconductor component 305 may include a respective set of one or more arrays of memory cells (e.g., one or more memory arrays 155), and the semiconductor component 310 may include control circuitry, processing circuitry, or both, that is configured to access the one or more arrays of memory cells (e.g., aspects of a local controller 150, aspects of a memory system controller 140). In some examples, a semiconductor component 305 may include one or more dies 240. In some implementations, a semiconductor component 310 may include at least some features of a host (e.g., of a host system 105), such as including aspects of a host processor (e.g., a processor 125), or a host system controller 120, or a combination thereof. In some implementations, a semiconductor component 310 may include a die 205.

Operations performed by the semiconductor system 300 (e.g., operations of the semiconductor component 310, operations of the semiconductor components 305) may generate heat, which may be distributed through the semiconductor system 300 in accordance with various thermal paths. However, in some implementations, a semiconductor component 310 may be associated with a larger footprint (e.g., a larger cross-section as viewed along the z-direction, a larger dimension along one or more direction in an xy-plane) than a semiconductor component 305, or a pattern of multiple semiconductor components 305 coupled with the semiconductor component 310. For example, as illustrated, the semiconductor component 310 may be associated with a dimension 345 along the y-direction that is greater than a dimension 340 along the y-direction that is associated with a respective semiconductor component 305.

To improve the uniformity (e.g., along an xy-plane) of thermal conductivity through the semiconductor system 300 (e.g., along the z-direction) and reduce the likelihood of hotspots (e.g., in locations of the semiconductor component 310 that are not coupled with a semiconductor component 305), the semiconductor system 300 may include a metallic material 315 over one or more portions of the semiconductor component 310 (e.g., over regions that are not coupled with a semiconductor component 305). For example, the semiconductor component 305-c may be coupled with a first portion of the surface of the semiconductor component 310 and the semiconductor component 305-d may be coupled with a second portion of the surface of the semiconductor component 310. The metallic material 315 may be coupled with a third portion of the surface of the semiconductor component 310 between the first portion and the second portion (e.g., a portion with a width 335 extending along the dimension 340). In some examples, a second metallic material 355 may extend through a portion of the semiconductor component 310 along a z-direction opposite from the third portion of the surface of the semiconductor component 310. For example, the second metallic material 355 may form a non-communicative TSV (also known as a thermal chimney) in the semiconductor component 310. The non-communicative TSV may conduct heat away from the semiconductor component 310.

The metallic material 315 may be continuous along (e.g., around) multiple sides of a semiconductor component 305. For example, the metallic material 315 may be over the third portion of the surface of the semiconductor component 310, adjacent to the semiconductor component 305-c along one or more sides of the semiconductor component 305-c, and further adjacent to the semiconductor component 305-d along one or more sides of the semiconductor component 305-d. Additionally, or alternatively, the metallic material 315 may be formed in multiple discontinuous portions along multiple sides of a semiconductor component 305. For example, the metallic material 315 may extend along a first side in a y-direction (e.g., parallel to the dimension 340), along a second side in the y-direction opposite the first side, along a third side in a direction 350 (e.g., parallel to an x-direction), and along a fourth side in the direction 350 opposite the third side.

The metallic material 315 may include (e.g., be formed from) any metal, including copper, nickel, cobalt, tungsten, silver, gold, or any combination thereof. In some examples, the metallic material 315 may extend along a z-direction opposite the semiconductor component 310 from the surface of the semiconductor component 310. Additionally, or alternatively, the metallic material 315 may extend along the z-direction opposite the semiconductor component 310 to an extent of a semiconductor component 305 opposite the semiconductor component 310. That is, the metallic material 315 may extend a height (e.g., along the z-direction, a thickness, one or more extents) that is similar to (e.g., the same as) a height of one or more semiconductor components 305. Because the metallic material 315 is implemented to provide a thermal path (e.g., rather than an electrical circuit functionality), the metallic material 315 may not include or couple electrically operable circuitry. For example, the metallic material 315 may be electrically isolated from circuitry of the semiconductor component 310 and from the circuitry of the semiconductor components 305.

As seen in the cross-sectional view 320, the semiconductor system 300 may include a dielectric material 330, a dielectric material 325, or both. The dielectric material 330 may be a dielectric liner that electrically separates the semiconductor components 305, the semiconductor component 310, or both from the metallic material 315. For example, the dielectric material 330 may be between the metallic material 315 and the semiconductor component 310, between the metallic material 315 and a respective semiconductor component 305, or both. In some examples, the dielectric material 330 may extend along the z-direction opposite the semiconductor component 310 to an extent of a semiconductor component 305 opposite the semiconductor component 310 (e.g., the dielectric material 330 may extend from the surface of the semiconductor component 310 to a height of a semiconductor component 305). The dielectric material 330 may include an aluminum nitride material, a nickel silicide material, a silicon oxide material, a silicon nitride material, or any combination thereof. The dielectric material 325 may include a mold compound material (e.g., an organic mold compound, an epoxy). The dielectric material 325 may be over the metallic material 315 and extend along the z-direction opposite the semiconductor component 310 to an extent of a semiconductor component 305 opposite the semiconductor component 310. In some other examples, dielectric material 325 may be omitted (e.g., replaced by a further extent of the metallic material 315).

The semiconductor components 305 may be coupled with the semiconductor component 310. In some examples, coupling the semiconductor components 305 with the semiconductor component 310 may result in one or more trenches (e.g., gaps) between respective semiconductor components 305. That is, the semiconductor components 305 may be separated by a width 335 along the y-direction, along the x-direction, or both (e.g., the trenches may extend in an x-direction, a y-direction, or both between semiconductor components 305). Additionally, or alternatively, one or more semiconductor components (e.g., wafers of semiconductor components 305) may be coupled with the semiconductor component 310, and trenches (e.g., trenches with the width 335 along the y-direction or the direction 350) may be formed through the one or more semiconductor components to form (e.g., singulate) the semiconductor components 305. The metallic material 315 (e.g., as well as the dielectric material 330 and the dielectric material 325, where applicable) may be formed in (e.g., deposited in) the trenches as part of forming a semiconductor system 300.

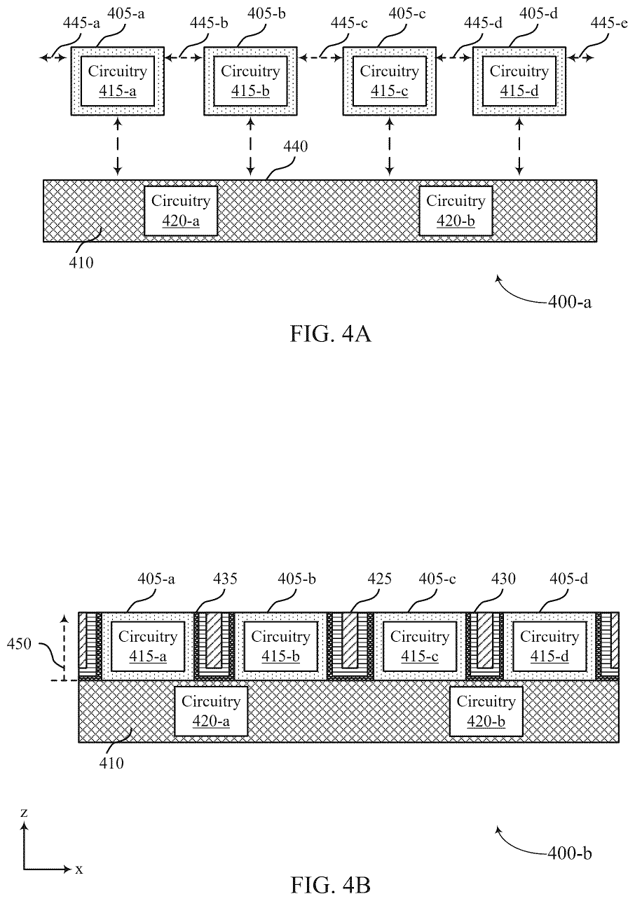

FIGS. 4A and 4B show examples of processing steps 400 that support thermal distribution in coupled semiconductor systems in accordance with examples as disclosed herein. The processing steps 400 may illustrate a cross-sectional view for forming a semiconductor system (e.g., including semiconductor components 405, a semiconductor component 410, and a metallic material 430), which may include features described with reference to the semiconductor system 300 of FIG. 3. Although FIGS. 4A and 4B illustrate examples of relative dimensions and quantities of various features, aspects of the processing steps 400 may be implemented with other relative dimensions or qualities of such features in accordance with examples as disclosed herein.

FIG. 4A illustrates a first processing step 400-a. In the first processing step 400-a, semiconductor components 405 (e.g., a semiconductor component 405-a, a semiconductor component 405-b, a semiconductor component 405-c, and a semiconductor component 405-d) may be bonded with respective first portions of a surface 440 of the semiconductor component 410. In some examples, the semiconductor component 410, the semiconductor components 405, or both, may include a respective stack of multiple semiconductor dies, or the semiconductor component 410 may include a stack of semiconductor wafers, among other examples.

The semiconductor component 410 may include circuitry 420 (e.g., circuitry 420-a and 420-b), and the semiconductor components 405 may each include respective circuitry 415 (e.g., circuitries 415-a, 415-b, 415-c, and 415-d) that is coupled with the circuitry 420 based on bonding with the respective first portion of the surface 440 of the semiconductor component 410. In an example implementation, the respective circuitries 415 may each include one or more arrays of memory cells, and the circuitry 420 may include control circuitry, processing circuitry, or both, configured to access the one or more arrays of memory cells. In some examples, the circuitry 420 and the respective circuitries 415 may extend through the respective stack of multiple semiconductor dies.

FIG. 4B illustrates a second processing step 400-b. In the second processing step 400-b, the metallic material 430 may be formed over one or more second portions 445 of the surface 440 of the semiconductor component 410 and adjacent to one or more of the semiconductor components 405 (e.g., overlapping at least in part along the z-direction) along one or more sides of the one or more semiconductor components 405 (e.g., along the x-direction, along the y-direction, or a combination thereof). In some examples, the metallic material 430 may be formed along a direction 450 opposite the semiconductor component 410 to an extent of the multiple semiconductor components 405 opposite the semiconductor component 410. The metallic material 430 may be electrically isolated from circuitry of the semiconductor component 410 including the circuitry 420 and from circuitry of the semiconductor components 405 including the respective circuitries 415.

In some examples, the second processing step 400-b may further include forming a dielectric material 435 over the one or more second portions 445-a, 445-b, 445-c, 445-d, and 445-e of the surface 440 of the semiconductor component 410 and along the one or more sides of the one or more of multiple semiconductor components 405. In such examples, the metallic material 430 may be formed over the dielectric material 435. The dielectric material 435 may be formed along the direction 450 opposite the semiconductor component 410 to an extent of the multiple semiconductor components 405 opposite the semiconductor component 410. Additionally, or alternatively, the second processing step 400-b may include forming a dielectric material 425 in a cavity of the metallic material 430. The dielectric material 425 may be formed along the direction 450 opposite the semiconductor component 410 to an extent of the multiple semiconductor components 405 opposite the semiconductor component 410.

In some examples, the processing steps 400 may further include forming multiple semiconductor systems, such as the semiconductor system 300. Each semiconductor system may include a respective portion of the semiconductor component 410 and a respective one or more of the semiconductor components 405. The multiple semiconductor systems may be formed based on cutting through the semiconductor component 410 and the metallic material 430, thereby isolating the circuitry 415 of the respective one or more semiconductor components 405 from the other semiconductor components 405. For example, a first semiconductor system may include a first portion of the semiconductor component 410 that is coupled with the semiconductor component 405-a and the semiconductor component 405-b. The first portion of the semiconductor component 410 may include circuitry 420-a that is configured to access circuitry 415-a of the semiconductor component 405-a and circuitry 415-b of the semiconductor component 405-b. The process of cutting the semiconductor component 410 and the metallic material 430 may be referred to as singulation or dicing. A singulation process may use a dicing saw or laser cutting tool, among other examples, to cut the semiconductor component 410 and the metallic material 430 into multiple semiconductor systems, dies, or chips.

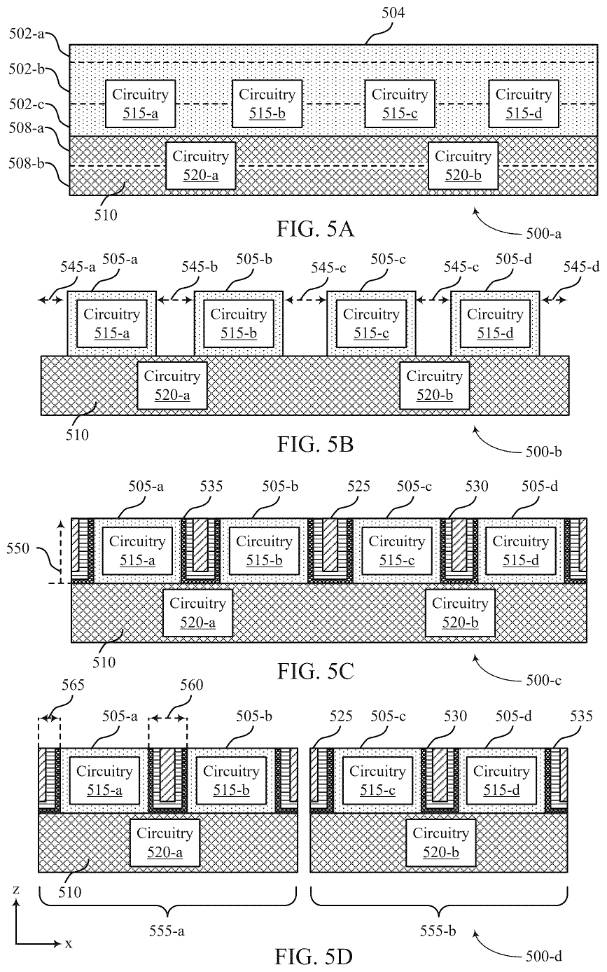

FIGS. 5A through 5D show examples of processing steps 500 that support thermal distribution in coupled semiconductor systems in accordance with examples as disclosed herein. The processing steps 500 may illustrate a cross-sectional view for forming a semiconductor system (e.g., including semiconductor components 505, a semiconductor component 510, and a metallic material 530), which may include features described with reference to a semiconductor system 300. Although FIGS. 5A through 5D illustrate examples of relative dimensions and quantities of various features, aspects of the processing steps 500 may be implemented with other relative dimensions or qualities of such features in accordance with examples as disclosed herein.

FIG. 5A illustrates a first processing step 500-a. In the first processing step 500-a, a semiconductor component 504 may be bonded with a semiconductor component 510. The semiconductor component 504 may include a first stack of multiple semiconductor dies 502 (e.g., a semiconductor die 502-a, a semiconductor die 502-b, a semiconductor die 502-c). Additionally, or alternatively, the semiconductor component 510 may include a second stack of multiple semiconductor dies 508 (e.g., a semiconductor die 508-a and a semiconductor die 508-b).

The semiconductor component 510 may include multiple circuitries 520 and the semiconductor component 504 may include multiple circuitries 515 that are each electrically coupled with a respective one of the multiple circuitries 520 based on the bonding (e.g., circuitry 515-a and 515-b coupled with circuitry 520-a, circuitry 515-c and circuitry 515-d coupled with circuitry 520-a). In some examples, the multiple circuitries 515 may each include one or more arrays of memory cells, and the multiple circuitries 520 may each include control circuitry, processing circuitry, or both configured to access the one or more arrays of memory cells. In some examples, the multiple circuitries 515 may extend through one or more semiconductor dies 502 of the first stack of multiple semiconductor dies 502, and the multiple circuitries 520 may extend through one or more semiconductor dies 508 of the second stack of multiple semiconductor dies 508. Although processing step 500-a illustrates an example in which multiple circuitries 515 are coupled with each circuitry 520, the described techniques may be implemented with a one-to-one, multiple-to-one, or one-to multiple coupling between circuitry 515 and circuitry 520.

FIG. 5B illustrates a second processing step 500-b. In the second processing step 500-b, trenches 545 may be formed through the semiconductor component 504 (e.g., between respective circuitries 515). In some examples, the trenches 545 (e.g., trenches 545-a, 545-b, 545-c, and 545-d) may be formed using one or more etching operations. An etching operation may use chemical methods, physical methods, or both, to remove materials from the semiconductor component 504. For example, the one or more etching operations may form trenches 545 using a dry etch, a wet etch, a sequence of a dry etch and a wet etch, or any combination thereof.

FIG. 5C illustrates a third processing step 500-c. In the third processing step 500-c, the metallic material 530 may be formed in the trenches 545. The metallic material 530 may be electrically isolated from the multiple circuitries 520 and from the multiple circuitries 515. In some examples, the metallic material 530 may be formed along a direction 550 opposite the semiconductor component 510 to an extent of a semiconductor component 505 opposite the semiconductor component 510.

In some examples, the third processing step 500-c may further include forming a dielectric material 535 in the trenches 545 and forming the metallic material 530 over the dielectric material 535. Additionally, or alternatively, the third processing step 500-c may include forming a dielectric material 525 in a cavity of the metallic material 530. The dielectric material 525 may be formed along the direction 550 opposite the semiconductor component 510 to an extent of the multiple semiconductor components 505 opposite the semiconductor component 510.

FIG. 5D illustrates a fourth processing step 500-d. In the fourth processing step 500-d, multiple semiconductor systems 555 may be formed based on cutting through (e.g., performing a singulation process on) the stacked semiconductor components 510 and at least the metallic material 530. Each semiconductor system 555 may include one or more of the circuitries 515 and the respective one or more of the circuitries 520. For example, a semiconductor system 555-a may include a first portion of the semiconductor component 510 that is coupled with the semiconductor component 505-a and the semiconductor component 505-b. The first portion of the semiconductor component 510 may include circuitry 520-a that is configured to access circuitry 515-a of the semiconductor component 505-a and circuitry 515-b of the semiconductor component 505-b. A semiconductor system 555-b may include a second portion of the semiconductor component 510 that is coupled with the semiconductor component 505-c and the semiconductor component 505-d. The second portion of the semiconductor component 510 may include circuitry 520-b that is configured to access circuitry 515-c of the semiconductor component 505-c and circuitry 515-d of the semiconductor component 505-d.

In some examples, an interior width 560 of the metallic material 530 may be different from an exterior width 565 of the metallic material 530 based on cutting through the semiconductor component 510 and the metallic material 530. For example, the exterior width 565 of the metallic material 530 that is adjacent to a first surface of the semiconductor component 505-a may be less than the interior width 560 of the metallic material 540 that is adjacent to a second surface opposite the first surface of the semiconductor component 505-a.

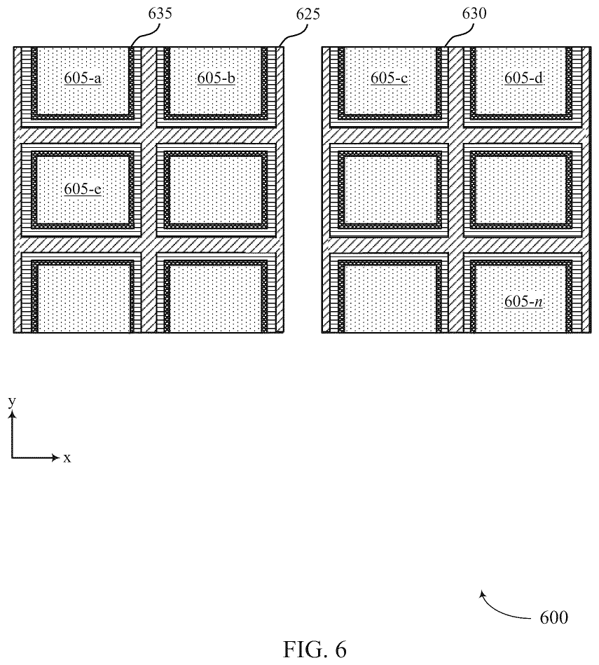

FIG. 6 shows an example of a top plan view 600 that supports thermal distribution in coupled semiconductor systems in accordance with examples as disclosed herein. The top plan view 600 may illustrate a top plan view of the cross-sectional views illustrated in the second processing step 400-b and the fourth processing step 500-d. The top plan view 600 illustrates an array of semiconductor components 605 (e.g., including a semiconductor component 605-a, a semiconductor component 605-b, a semiconductor 605-c, a semiconductor component 605-d, a semiconductor component 605-e, and so on up to a semiconductor component 605-n). The top plan view 600 also illustrates a metallic material 630, a dielectric material 635, and a second dielectric material 625, which may correspond to the materials described in FIGS. 3 through 5. In some examples, the metallic material 630 may extend along an x-direction and along a y-direction adjacent to one or more sides of a respective semiconductor component 605. For example, the metallic material 630 may be adjacent to all four sides of the semiconductor component 605-e.

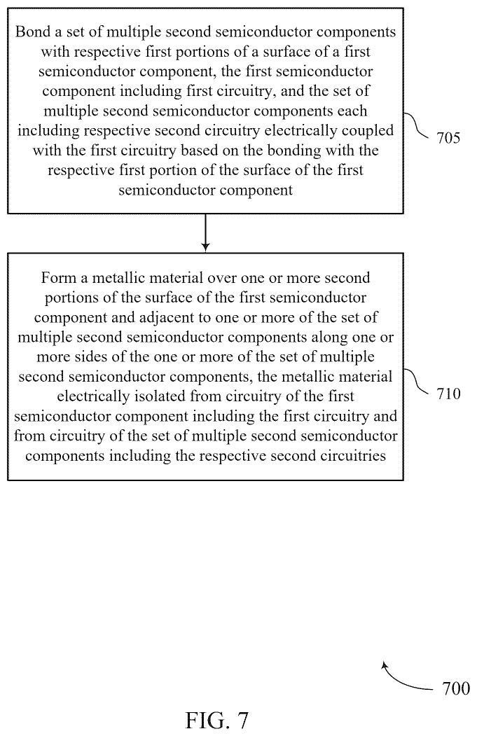

FIG. 7 shows a flowchart illustrating a method 700 that supports thermal distribution in coupled semiconductor systems in accordance with examples as disclosed herein. The operations of method 700 may be implemented by a manufacturing system or its components as described herein. For example, the operations of method 700 may be performed by a manufacturing system as described with reference to FIGS. 1 through 6. In some examples, a manufacturing system may execute a set of instructions to control the functional elements of the device to perform the described functions. Additionally, or alternatively, the manufacturing system may perform aspects of the described functions using special-purpose hardware.

At 705, the method may include bonding a set of multiple second semiconductor components (e.g., semiconductor components 405) with respective first portions of a surface (e.g., surface 440) of a first semiconductor component (e.g., semiconductor component 410), the first semiconductor component including first circuitry (e.g., circuitry 415), and the set of multiple second semiconductor components each including respective second circuitry (e.g., circuitry 420) electrically coupled with the first circuitry based on the bonding with the respective first portion of the surface of the first semiconductor component.

At 710, the method may include forming a metallic material (e.g., metallic material 430) over one or more second portions of the surface of the first semiconductor component and adjacent to one or more of the set of multiple second semiconductor components along one or more sides of the one or more of the set of multiple second semiconductor components, the metallic material electrically isolated from circuitry of the first semiconductor component including the first circuitry and from circuitry of the plurality of second semiconductor components including the respective second circuitries.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for bonding a plurality of second semiconductor components with respective first portions of a surface of a first semiconductor component, the first semiconductor component including first circuitry, and the plurality of second semiconductor components each including respective second circuitry electrically coupled with the first circuitry based on the bonding with the respective first portion of the surface of the first semiconductor component and forming a metallic material over one or more second portions of the surface of the first semiconductor component and adjacent to one or more of the plurality of second semiconductor components along one or more sides of the one or more of the plurality of second semiconductor components, the metallic material electrically isolated from circuitry of the first semiconductor component including the first circuitry and from circuitry of the plurality of second semiconductor components including the respective second circuitries.

Aspect 2: The method, apparatus, or non-transitory computer-readable medium of aspect 1, where the respective second circuitries each include one or more arrays of memory cells and the first circuitry includes control circuitry, processing circuitry, or both configured to access the one or more arrays of memory cells.

Aspect 3: The method, apparatus, or non-transitory computer-readable medium of any of aspects 1 through 2, where the first semiconductor component, the plurality of second semiconductor components, or both include a respective stack of multiple semiconductor dies.

Aspect 4: The method, apparatus, or non-transitory computer-readable medium of any of aspects 1 through 3, where the metallic material is formed along a direction opposite the first semiconductor component to an extent of the plurality of second semiconductor components opposite the first semiconductor component.

Aspect 5: The method, apparatus, or non-transitory computer-readable medium of any of aspects 1 through 4, further including operations, features, circuitry, logic, means, or instructions, or any combination thereof for forming a dielectric material over the one or more second portions of the surface of the first semiconductor component and along the one or more sides of the one or more of the plurality of second semiconductor components and forming the metallic material over the dielectric material.

Aspect 6: The method, apparatus, or non-transitory computer-readable medium of aspect 5, where the dielectric material is formed along a direction opposite the first semiconductor component to an extent of the plurality of second semiconductor components opposite the first semiconductor component.

Aspect 7: The method, apparatus, or non-transitory computer-readable medium of any of aspects 1 through 6, further including operations, features, circuitry, logic, means, or instructions, or any combination thereof for forming a second dielectric material in a cavity of the metallic material.

Aspect 8: The method, apparatus, or non-transitory computer-readable medium of aspect 7, where the second dielectric material is formed along a direction opposite the first semiconductor component to an extent of the plurality of second semiconductor components opposite the first semiconductor component.

Aspect 9: The method, apparatus, or non-transitory computer-readable medium of any of aspects 1 through 8, further including operations, features, circuitry, logic, means, or instructions, or any combination thereof for forming a plurality of semiconductor systems, each including a respective portion of the first semiconductor component and a respective one or more of the plurality of second semiconductor components, based on cutting through the first semiconductor component and the metallic material.

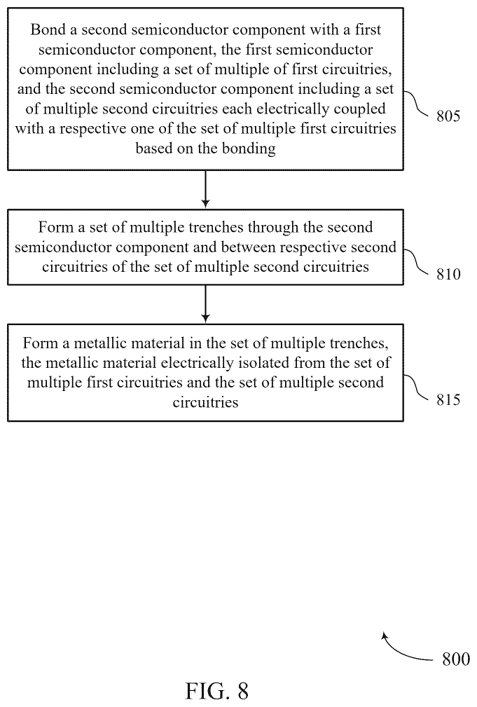

FIG. 8 shows a flowchart illustrating a method 800 that supports thermal distribution in coupled semiconductor systems in accordance with examples as disclosed herein. The operations of method 800 may be implemented by a manufacturing system or its components as described herein. For example, the operations of method 800 may be performed by a manufacturing system as described with reference to FIGS. 1 through 6. In some examples, a manufacturing system may execute a set of instructions to control the functional elements of the device to perform the described functions. Additionally, or alternatively, the manufacturing system may perform aspects of the described functions using special-purpose hardware.

At 805, the method may include bonding a second semiconductor component (e.g., semiconductor component 504) with a first semiconductor component (e.g., semiconductor component 510), the first semiconductor component including a set of multiple first circuitries (e.g., circuitries 520), and the second semiconductor component including a set of multiple second circuitries (e.g., circuitries 515) each electrically coupled with a respective one of the set of multiple first circuitries based on the bonding.

At 810, the method may include forming a set of multiple trenches (e.g., trenches 545) through the second semiconductor component and between respective second circuitries of the set of multiple second circuitries.

At 815, the method may include forming a metallic material (e.g., metallic material 530) in the plurality of trenches, the metallic material electrically isolated from the set of multiple first circuitries and the set of multiple second circuitries.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 10: A method, apparatus, or non-transitory computer-readable medium including operations, features, circuitry, logic, means, or instructions, or any combination thereof for bonding a second semiconductor component with a first semiconductor component, the first semiconductor component including a plurality of first circuitries, and the second semiconductor component including a plurality of second circuitries each electrically coupled with a respective one of the plurality of first circuitries based on the bonding; forming a plurality of trenches through the second semiconductor component and between respective second circuitries of the plurality of second circuitries; and forming a metallic material in the plurality of trenches, the metallic material electrically isolated from the plurality of first circuitries and the plurality of second circuitries.

Aspect 11: The method, apparatus, or non-transitory computer-readable medium of aspect 10, where the plurality of second circuitries each include one or more arrays of memory cells and the plurality of first circuitries each include control circuitry, processing circuitry, or both configured to access the one or more arrays of memory cells.

Aspect 12: The method, apparatus, or non-transitory computer-readable medium of any of aspects 10 through 11, where the first semiconductor component, the second semiconductor component, or both includes a respective stack of multiple semiconductor dies.

Aspect 13: The method, apparatus, or non-transitory computer-readable medium of any of aspects 10 through 12, where the metallic material is formed along a direction opposite the first semiconductor component to an extent of the second semiconductor component opposite the first semiconductor component.

Aspect 14: The method, apparatus, or non-transitory computer-readable medium of any of aspects 10 through 13, further including operations, features, circuitry, logic, means, or instructions, or any combination thereof for forming a dielectric material in the plurality of trenches and forming the metallic material over the dielectric material.

Aspect 15: The method, apparatus, or non-transitory computer-readable medium of any of aspects 10 through 14, further including operations, features, circuitry, logic, means, or instructions, or any combination thereof for forming a plurality of semiconductor systems, each including one or more of the plurality of second circuitries and the respective one or more of the plurality of first circuitries, based on cutting through the first semiconductor component and the metallic material.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 16: A semiconductor system, including: a first semiconductor component including first circuitry; a second semiconductor component bonded with a first portion of a surface of the first semiconductor component, the second semiconductor component including second circuitry electrically coupled with the first circuitry via the bond with the first portion of the surface of the first semiconductor component; and a metallic material over a second portion of the surface of the first semiconductor component and adjacent to the second semiconductor component along one or more sides of the second semiconductor component, the metallic material electrically isolated from circuitry of the first semiconductor component including the first circuitry and from circuitry of the second semiconductor component including the second circuitry.

Aspect 17: The semiconductor system of aspect 16, further including: a third semiconductor component bonded with a third portion of the surface of the first semiconductor component, the third semiconductor component including third circuitry electrically coupled with the first circuitry via the bond with the third portion of the surface of the first semiconductor component, where the metallic material is further adjacent to the third semiconductor component along one or more sides of the third semiconductor component, and the metallic material is electrically isolated from circuitry of the third semiconductor component including the third circuitry.

Aspect 18: The semiconductor system of any of aspects 16 through 17, where: the second circuitry includes one or more arrays of memory cells; and the first circuitry includes control circuitry, processing circuitry, or both configured to access the one or more arrays of memory cells.

Aspect 19: The semiconductor system of any of aspects 16 through 18, where the first semiconductor component, the second semiconductor component, or both includes a respective stack of multiple semiconductor dies.

Aspect 20: The semiconductor system of any of aspects 16 through 19, where the metallic material extends along a direction opposite the first semiconductor component from the surface of the first semiconductor component.

Aspect 21: The semiconductor system of any of aspects 16 through 20, where the metallic material extends along a direction opposite the first semiconductor component to an extent of the second semiconductor component opposite the first semiconductor component.

Aspect 22: The semiconductor system of any of aspects 16 through 21, where the metallic material is continuous along multiple sides of the second semiconductor component.

Aspect 23: The semiconductor system of any of aspects 16 through 22, where the metallic material is formed in multiple discontinuous portions along multiple sides of the second semiconductor component.

Aspect 24: The semiconductor system of any of aspects 16 through 23, further including: a dielectric material between the metallic material and the first semiconductor component, between the metallic material and the second semiconductor component, or both.

Aspect 25: The semiconductor system of aspect 24, where the dielectric material extends along a direction opposite the first semiconductor component to an extent of the second semiconductor component opposite the first semiconductor component.

Aspect 26: The semiconductor system of any of aspects 24 through 25, where the dielectric material includes aluminum nitride, nickel silicide, silicon oxide, silicon nitride, or combination thereof.

Aspect 27: The semiconductor system of any of aspects 16 through 26, further including: a second dielectric material over the metallic material and extending along a direction opposite the first semiconductor component to an extent of the second semiconductor component opposite the first semiconductor component.

Aspect 28: The semiconductor system of aspect 27, where the second dielectric material includes a mold compound material.

Aspect 29: The semiconductor system of any of aspects 16 through 28, further including: a second metallic material extending through a portion of the first semiconductor component along a direction opposite from the second portion of the surface of the first semiconductor component.

Aspect 30: The semiconductor system of any of aspects 16 through 29, where the metallic material includes copper, nickel, cobalt, tungsten, silver, gold, or a combination thereof.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor component including first circuitry;
a second semiconductor component bonded with a first portion of a surface of the first semiconductor component, the second semiconductor component including second circuitry electrically coupled with the first circuitry via the bond with the first portion of the surface of the first semiconductor component; and
a metallic material over a second portion of the surface of the first semiconductor component and adjacent to the second semiconductor component along one or more sides of the second semiconductor component, the metallic material electrically isolated from circuitry of the first semiconductor component including the first circuitry and from circuitry of the second semiconductor component including the second circuitry.

2. The semiconductor system of claim 1, further comprising:
a third semiconductor component bonded with a third portion of the surface of the first semiconductor component, the third semiconductor component including third circuitry electrically coupled with the first circuitry via the bond with the third portion of the surface of the first semiconductor component,
wherein the metallic material is further adjacent to the third semiconductor component along one or more sides of the third semiconductor component, and the metallic material is electrically isolated from circuitry of the third semiconductor component including the third circuitry.

3. The semiconductor system of claim 1, wherein:
the second circuitry comprises one or more arrays of memory cells; and
the first circuitry comprises control circuitry, processing circuitry, or both configured to access the one or more arrays of memory cells.

4. The semiconductor system of claim 1, wherein the first semiconductor component, the second semiconductor component, or both comprises a respective stack of multiple semiconductor dies.

5. The semiconductor system of claim 1, wherein the metallic material extends along a direction opposite the first semiconductor component from the surface of the first semiconductor component.

6. The semiconductor system of claim 1, wherein the metallic material extends along a direction opposite the first semiconductor component to an extent of the second semiconductor component opposite the first semiconductor component.

7. The semiconductor system of claim 1, wherein the metallic material is continuous along multiple sides of the second semiconductor component.

8. The semiconductor system of claim 1, wherein the metallic material is formed in multiple discontinuous portions along multiple sides of the second semiconductor component.

9. The semiconductor system of claim 1, further comprising:
a dielectric material between the metallic material and the first semiconductor component, between the metallic material and the second semiconductor component, or both.

10. The semiconductor system of claim 9, wherein the dielectric material extends along a direction opposite the first semiconductor component to an extent of the second semiconductor component opposite the first semiconductor component.

11. The semiconductor system of claim 9, wherein the dielectric material comprises aluminum nitride, nickel silicide, silicon oxide, silicon nitride, or combination thereof.

12. The semiconductor system of claim 1, further comprising:
a second dielectric material over the metallic material and extending along a direction opposite the first semiconductor component to an extent of the second semiconductor component opposite the first semiconductor component.

13. The semiconductor system of claim 12, wherein the second dielectric material comprises a mold compound material.

14. The semiconductor system of claim 1, further comprising:
a second metallic material extending through a portion of the first semiconductor component along a direction opposite from the second portion of the surface of the first semiconductor component, wherein the metallic material comprises copper, nickel, cobalt, tungsten, silver, gold, or a combination thereof.

15. A method, comprising:
bonding a plurality of second semiconductor components with respective first portions of a surface of a first semiconductor component, the first semiconductor component including first circuitry, and the plurality of second semiconductor components each including respective second circuitry electrically coupled with the first circuitry based on the bonding with the respective first portion of the surface of the first semiconductor component; and
forming a metallic material over one or more second portions of the surface of the first semiconductor component and adjacent to one or more of the plurality of second semiconductor components along one or more sides of the one or more of the plurality of second semiconductor components, the metallic material electrically isolated from circuitry of the first semiconductor component including the first circuitry and from circuitry of the plurality of second semiconductor components including the respective second circuitries.

16. The method of claim 15, wherein:
the respective second circuitries each comprise one or more arrays of memory cells; and
the first circuitry comprises control circuitry, processing circuitry, or both configured to access the one or more arrays of memory cells.

17. The method of claim 15, wherein the first semiconductor component, the plurality of second semiconductor components, or both comprise a respective stack of multiple semiconductor dies.

18. The method of claim 15, wherein the metallic material is formed along a direction opposite the first semiconductor component to an extent of the plurality of second semiconductor components opposite the first semiconductor component.

19. The method of claim 15, further comprising:
forming a dielectric material over the one or more second portions of the surface of the first semiconductor component and along the one or more sides of the one or more of the plurality of second semiconductor components; and
forming the metallic material over the dielectric material.

20. The method of claim 19, wherein the dielectric material is formed along a direction opposite the first semiconductor component to an extent of the plurality of second semiconductor components opposite the first semiconductor component.

21. The method of claim 15, further comprising:
forming a second dielectric material in a cavity of the metallic material, wherein the second dielectric material is formed along a direction opposite the first semiconductor component to an extent of the plurality of second semiconductor components opposite the first semiconductor component.

22. The method of claim 15, further comprising:
forming a plurality of semiconductor systems, each including a respective portion of the first semiconductor component and a respective one or more of the plurality of second semiconductor components, based on cutting through the first semiconductor component and the metallic material.

23. A method, comprising:
bonding a second semiconductor component with a first semiconductor component, the first semiconductor component including a plurality of first circuitries, and the second semiconductor component including a plurality of second circuitries each electrically coupled with a respective one of the plurality of first circuitries based on the bonding;
forming a plurality of trenches through the second semiconductor component and between respective second circuitries of the plurality of second circuitries; and
forming a metallic material in the plurality of trenches, the metallic material electrically isolated from the plurality of first circuitries and the plurality of second circuitries.

24. The method of claim 23, wherein:
the plurality of second circuitries each comprise one or more arrays of memory cells; and
the plurality of first circuitries each comprise control circuitry, processing circuitry, or both configured to access the one or more arrays of memory cells.

25. The method of claim 23, wherein the first semiconductor component, the second semiconductor component, or both comprises a respective stack of multiple semiconductor dies.

26. The method of claim 23, wherein the metallic material is formed along a direction opposite the first semiconductor component to an extent of the second semiconductor component opposite the first semiconductor component.

27. The method of claim 23, further comprising:
forming a dielectric material in the plurality of trenches; and
forming the metallic material over the dielectric material.

28. The method of claim 23, further comprising:
forming a plurality of semiconductor systems, each including one or more of the plurality of second circuitries and the respective one or more of the plurality of first circuitries, based on cutting through the first semiconductor component and the metallic material.

29. A semiconductor system formed by a process, comprising:
bonding a plurality of second semiconductor components with respective first portions of a surface of a first semiconductor component, the first semiconductor component including first circuitry, and the plurality of second semiconductor components each including respective second circuitry electrically coupled with the first circuitry based on the bonding with the respective first portion of the surface of the first semiconductor component; and
forming a metallic material over one or more second portions of the surface of the first semiconductor component and adjacent to one or more of the plurality of second semiconductor components along one or more sides of the one or more of the plurality of second semiconductor components, the metallic material electrically isolated from circuitry of the first semiconductor component including the first circuitry and from circuitry of the plurality of second semiconductor components including the respective second circuitries.

30. A semiconductor system formed by a process, comprising:
bonding a second semiconductor component with a first semiconductor component, the first semiconductor component including a plurality of first circuitries, and the second semiconductor component including a plurality of second circuitries each electrically coupled with a respective one of the plurality of first circuitries based on the bonding;
forming a plurality of trenches through the second semiconductor component and between respective second circuitries of the plurality of second circuitries; and
forming a metallic material in the plurality of trenches, the metallic material electrically isolated from the plurality of first circuitries and the plurality of second circuitries.
